(19) United States
(12) Patent Application Publication
(10) Pub. No.: US 2025/0169147 A1
(43) Pub. Date: May 22, 2025

(54) OPTIMIZED INNER SPACER WITH BACKSIDE CONTACT

(71) Applicant: INTERNATIONAL BUSINESS MACHINES CORPORATION, ARMONK, NY (US)

(72) Inventors: Ruilong Xie, Niskayuna, NY (US); Julien Frougier, Albany, NY (US); Alexander Reznicek, Troy, NY (US); Daniel Schmidt, Niskayuna, NY (US)

(21) Appl. No.: 18/513,736

(22) Filed: Nov. 20, 2023

(51) Int. Cl. H01L 29/417; H01L 29/06; H01L 29/423; H01L 29/66; H01L 29/775; H01L 29/786

(52) U.S. Cl. CPC H10D 64/258; H10D 30/014; H10D 30/43; H10D 30/6735; H10D 30/6757; H10D 62/121; H10D 64/018; H10D 64/254

(57) ABSTRACT

A microelectronic structure that includes a nanosheet transistor. The nanosheet transistor includes a source epi and a drain epi. A first inner spacer located adjacent to the source epi, where the first inner spacer has a first width as measured perpendicular to a gate direction. A second inner spacer located adjacent to the drain epi. The second inner spacer has second width as measured perpendicular to the gate direction. The first width and the second width are different.

### BACKGROUND

The present invention generally relates to the field of microelectronics, and more particularly to the formation of a thinner inner spacer adjacent to a source/drain connected to a backside contact.

Nanosheet is the lead device architecture in continuing CMOS scaling. However, nanosheet technology has shown issues when scaling down such that as the devices become smaller and closer together, they are interfering with each other. With the number of devices being fitted in a smaller area it is becoming harder to form separate backside contacts that have enough surface contact with the source/drains.

### BRIEF SUMMARY

Additional aspects and/or advantages will be set forth in part in the description which follows and, in part, will be apparent from the description, or may be learned by practice of the invention.

A microelectronic structure that includes a nanosheet transistor. The nanosheet transistor includes a source epi and a drain epi. A first inner spacer located adjacent to the source epi, where the first inner spacer has a first width as measured perpendicular to a gate direction. A second inner spacer located adjacent to the drain epi. The second inner spacer has second width as measured perpendicular to the gate direction. The first width and the second width are different.

A microelectronic structure that includes a nanosheet transistor. The nanosheet transistor includes a source epi and a drain epi. The nanosheet transistor includes a plurality of channel layers. A first inner spacer located adjacent to the source epi, where the first inner spacer has a first width as measured perpendicular to a gate direction. A second inner spacer located adjacent to the drain epi. The second inner spacer has second width as measured perpendicular to the gate direction. The first width and the second width are different.

A method including the steps of forming a nanosheet transistor. The nanosheet transistor includes a source epi and a drain epi. Forming a first inner spacer located adjacent to the source epi, where the first inner spacer has a first width as measured perpendicular to a gate direction. Forming a second inner spacer located adjacent to the drain epi. The second inner spacer has second width as measured perpendicular to the gate direction. The first width and the second width are different.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of a plurality of nanosheet transistors, in accordance with the embodiment of the present invention.

FIG. 2 illustrates a cross section X of the nanosheet transistor after the formation of a dummy gate, hardmask, and gate spacers on top of nano stack, in accordance with the embodiment of the present invention.

FIG. 3 illustrates a cross section Y of the source/drain region after the separation of the nano stack into multiple columns and the formation of the gate spacer, in accordance with the embodiment of the present invention.

FIG. 4 illustrates a cross section X of the nanosheet transistor after the formation of the source/drain regions by separating nano stack into a plurality of columns, in accordance with the embodiment of the present invention.

FIG. 5 illustrates a cross section Y of the source/drain region after the formation of the source/drain regions by separating nano stack into a plurality of columns, in accordance with the embodiment of the present invention.

FIG. 6 illustrates a cross section X of the nanosheet transistor after the formation of a first lithography layer and the patterning of a placeholder trench, in accordance with the embodiment of the present invention.

FIG. 7 illustrates a cross section Y of the source/drain region after the formation of a first lithography layer and the patterning of a placeholder trench, in accordance with the embodiment of the present invention.

FIG. 8 illustrates a cross section X of the nanosheet transistor after the recessing of the sacrificial layers, in accordance with the embodiment of the present invention.

FIG. 9 illustrates a cross section X of the nanosheet transistor after the formation of a first inner spacer, in accordance with the embodiment of the present invention.

FIG. 10 illustrates a cross section X of the nanosheet transistor after the removal of the first lithography layer and the formation of the placeholder, in accordance with the embodiment of the present invention.

FIG. 11 illustrates a cross section Y of the source/drain region after the removal of the first lithography layer and the formation of the placeholder, in accordance with the embodiment of the present invention.

FIG. 12 illustrates a cross section X of the nanosheet transistor after the recessing of the sacrificial layers and the formation of the second inner spacer, in accordance with the embodiment of the present invention.

FIG. 13 illustrates a cross section X of the nanosheet transistor after the formation of the source/drain epis and the formation of the frontside interlayer dielectric layer, in accordance with the embodiment of the present invention.

FIG. 14 illustrates a cross section Y of the source/drain region after the formation of the source/drain epis and the formation of the frontside interlayer dielectric layer, in accordance with the embodiment of the present invention.

FIG. 15 illustrates a cross section X of the nanosheet transistor after the removal of the dummy gate, and the sacrificial layers and the formation of the gate, in accordance with the embodiment of the present invention.

FIG. 16 illustrates a cross section X of the nanosheet transistor after the formation of the additional the frontside interlayer dielectric layer, formation of frontside source/drain contacts, a back-end-of-the-line (BEOL) layer, and a carrier wafer, in accordance with the embodiment of the present invention.

FIG. 17 illustrates a cross section Y of the source/drain region after the formation of the additional the frontside interlayer dielectric layer, formation of frontside source/drain contacts, a back-end-of-the-line (BEOL) layer, and a carrier wafer, in accordance with the embodiment of the present invention.

FIG. 18 illustrates a cross section X of the nanosheet transistor after flipping over the nano stacks for backside processing and the removal of the first substrate, the etch stop, and the second substrate, in accordance with the embodiment of the present invention.

FIG. 19 illustrates a cross section Y of the source/drain region after flipping over the nano stacks for backside processing and the removal of the first substrate, the etch stop, and the second substrate, in accordance with the embodiment of the present invention.

FIG. 20 illustrates a cross section X of the nanosheet transistor after formation of a backside interlayer dielectric layer, in accordance with the embodiment of the present invention.

FIG. 21 illustrates a cross section Y of the source/drain region after formation of a backside interlayer dielectric layer, in accordance with the embodiment of the present invention.

FIG. 22 illustrates a cross section X of the nanosheet transistor after the removal of the placeholder, formation of the backside contact, formation of a backside metal lines, and the formation of a backside-power-distribution-network (BSPDN), in accordance with the embodiment of the present invention.

FIG. 23 illustrates a cross section Y of the source/drain region after the removal of the placeholder, formation of the backside contact, formation of a backside metal lines, and the formation of a backside-power-distribution-network (BSPDN), in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of +8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will be packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards the formation of a first inner spacer located adjacent to a source epi that is connected to a backside contact (or a frontside contact) while a second inner spacer is located adjacent to the drain epi. The first inner spacer has a first thickness/width/dimension and the second inner spacer has a second thickness/width/dimension, where the first thickness/width/dimension is smaller than the second thickness/width/dimension. The thinner inner spacer or the first inner spacer and the thicker inner spacer or the second inner spacer are made at different processing steps which allows for the differences in thickness/width/dimension of the inner spacers. This allows for the thinner inner spacer to be comprised of the same material as the thicker inner spacer or it can be comprised of a different material. Furthermore, the thinner inner spacer has dielectric constant higher k value than thicker inner spacer. The thinner inner spacer at source epi side provides better electrostatic control and more immune towards short channel effects.

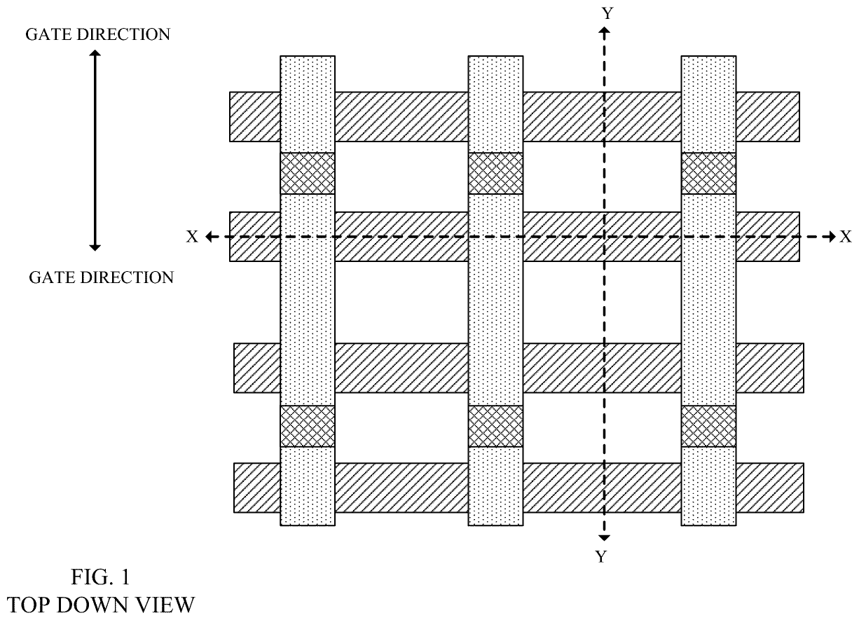

FIG. 1 illustrates a top-down view of multiple devices, in accordance with the embodiment of the present invention. The cross-section X extends horizontally through nanosheet transistors. Cross section Y is perpendicular to cross section X, where cross section Y is through a source/drain region that spans across multiple adjacent nanosheet transistors. Cross-section X is perpendicular to the gate direction and cross-section Y is parallel to the gate direction.

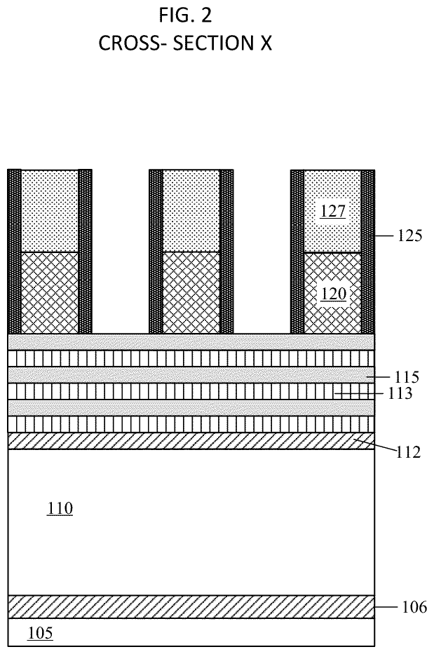

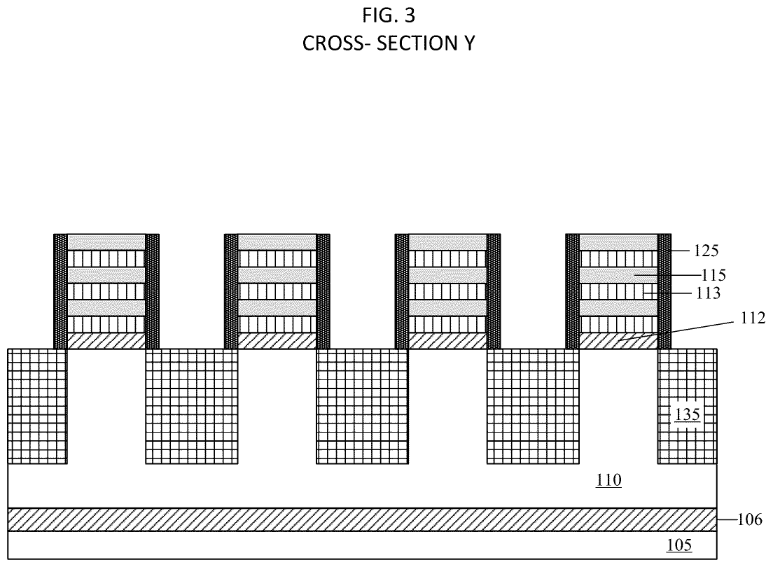

Referring now to FIGS. 2 and 3, a structure is shown during an intermediate step of a method of fabricating stacked nano devices, such as, a stacked nanosheet transistor structure after separation of the nano stack into multiple columns and the formation of the gate spacer, according to an embodiment of the invention.

FIGS. 2 and 3 illustrate the processing stage after the formation of a dummy gate 120, hardmask 127, and gate spacers 125 on top of nano stack.

FIG. 2 illustrates the nano stack of the nanosheet transistors that includes a first substrate 105, an etch stop 106, a second substrate 110, a dummy gate 120, a hardmask 127, and a gate spacer 125. The nano stack is comprised of a plurality of alternating layers that include channel layers 115, and sacrificial layers 113. The plurality of channel layers 115 can be comprised of, for example, Si. The plurality of sacrificial layers 113 can be comprised of SiGe, where Ge is in the percentage of 15 to 35%. Separate columns are located on top of the nano stack, where each column includes the dummy gate 120, the hardmask 127, and the gate spacer 125 are located on top of the nano stack.

The first substrate 105 and the second substrate 110 can be, for example, a material including, but not necessarily limited to, silicon (Si), silicon germanium (SiGe), Si: C (carbon doped silicon), carbon doped silicon germanium (SiGe: C), III-V, II-V compound semiconductor or another like semiconductor. In addition, multiple layers of the semiconductor materials can be used as the semiconductor material of the first substrate 105 and the second substrate 110. In some embodiments, first substrate 105 and the second substrate 110 includes both semiconductor materials and dielectric materials. The semiconductor first substrate 105 and the second substrate 110 may also comprise an organic semiconductor or a layered semiconductor such as, for example, Si/SiGe, a silicon-on-insulator or a SiGe-on-insulator. A portion or the entire semiconductor first substrate 105 and the second substrate 110 may also be comprised of an amorphous, polycrystalline, or monocrystalline. The semiconductor first substrate 105 and the second substrate 110 may be doped, undoped or contain doped regions and undoped regions therein.

FIG. 3 illustrates a cross section through the source/drain region, where the cross section is in parallel to the gate direction. FIG. 3 illustrates a plurality of nano stack columns that include channel layers 115, sacrificial layers 113, and the bottom dielectric isolation layer 112. Each of the columns has a gate spacer 125 located on the sides of the column. The separation of the alternating layers into a plurality of columns causes trenches (not shown) to be formed in the second substrate 110. These trenches are filled in with a shallow trench isolation layer 135.

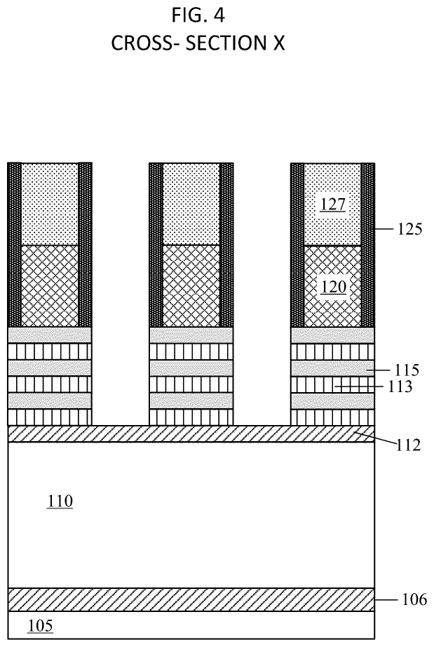

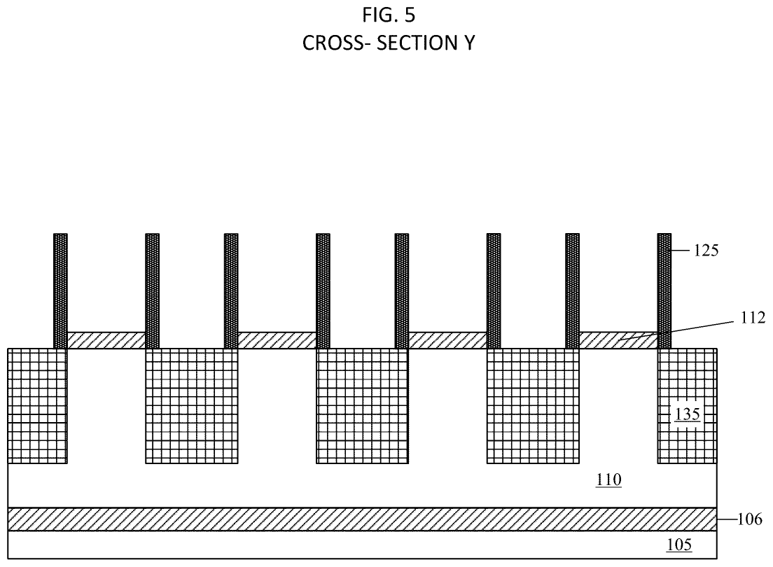

FIGS. 4 and 5 illustrate the processing stage after the formation of the source/drain regions by separating the nano stack into a plurality of columns. The nano stack is etched and separated into a plurality of columns, as illustrated in FIG. 4. The source/drain region is created by the removal of these portions of the nano stack.

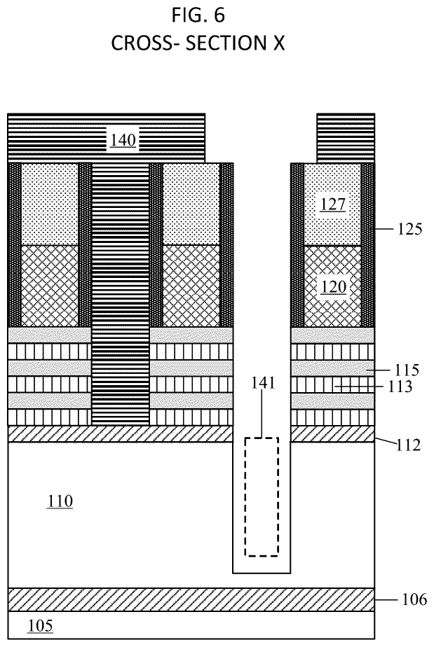

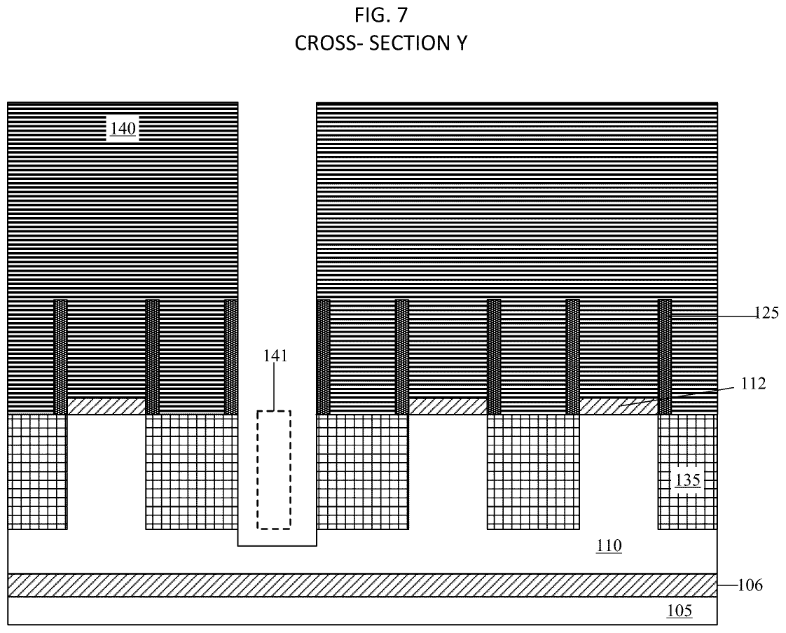

FIGS. 6 and 7 illustrate the processing stage after the formation of a first lithography layer 140 and the patterning of a placeholder trench 141. A first lithography layer 140 is deposited to form a protective layer on top of the nano device/nanosheet transistors. The first lithography layer 140 is patterned and a placeholder trench 141 is etched into the second substrate 110. The placeholder trench 141 is located within the source/drain region, as illustrated in FIG. 6. The patterning of the first lithography layer 140 exposes a sidewall of two adjacent nano stack columns, such that a sidewall of the channel layers 115 and the sacrificial layers 113 of each of the adjacent nano stack columns are exposed. FIG. 7 illustrates that the placeholder trench 141 can expose the sidewalls of adjacent sections of the shallow trench isolation layer 135.

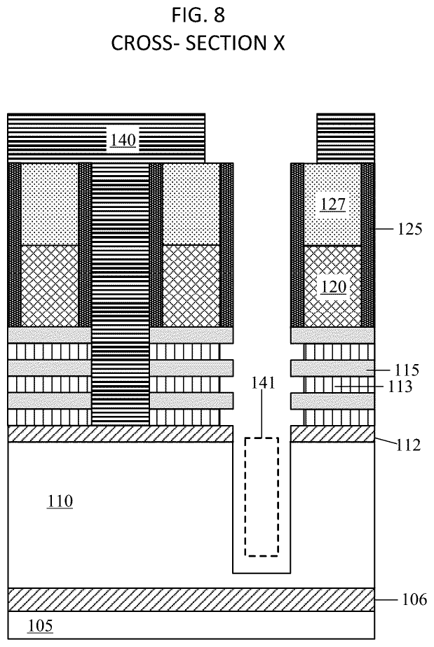

FIG. 8 illustrates the processing stage after the recessing of the sacrificial layers 113. The sacrificial layers 113 that were exposed by the formation of the placeholder trench 141 are recessed. The recessing of the sacrificial layers 113 creates empty space for the formation of an inner spacer. At this point only the sacrificial layers 113 exposed by the etching of the placeholder trench 141 are recessed, while the other sacrificial layers 113 are not recessed. The first lithography layer 140 protects portions of the sacrificial layers 113 from being recessed. For example, as illustrated in FIG. 8, the center nano stack column has only one end (or one side) of the sacrificial layers 113 etched/recessed, while the other end (or other side) of the sacrificial layers 113 are not etch. The first lithography layer 140 prevents the etching/recessing of the not exposed sacrificial layers 113.

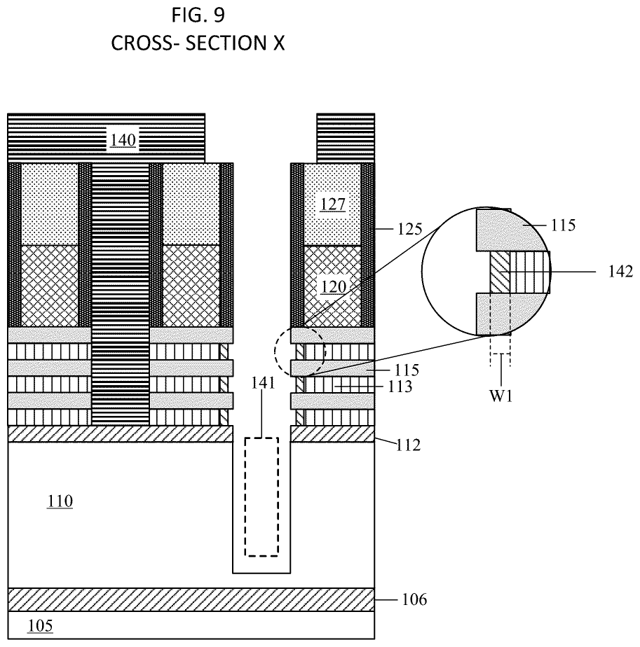

FIG. 9 illustrates the processing stage after the formation of a first inner spacer 142. The first inner spacer 142 is formed in the areas created by the recessing of the sacrificial layers 113. The first inner spacer 142 will be also referred to as the thinner inner spacer 142. The width of the first inner spacer 142 does not extend to the end of the channel layers 115, as illustrated by the magnified view of one of the first inner spacers 142. The first inner spacers 142 has a first width W1 in the range for about 1 to 4 nanometers. The first width W1, or thickness, dimensions is measured perpendicular to the gate direction. The first inner spacer 142 will be located adjacent to the source epi, which will be described in further detail below.

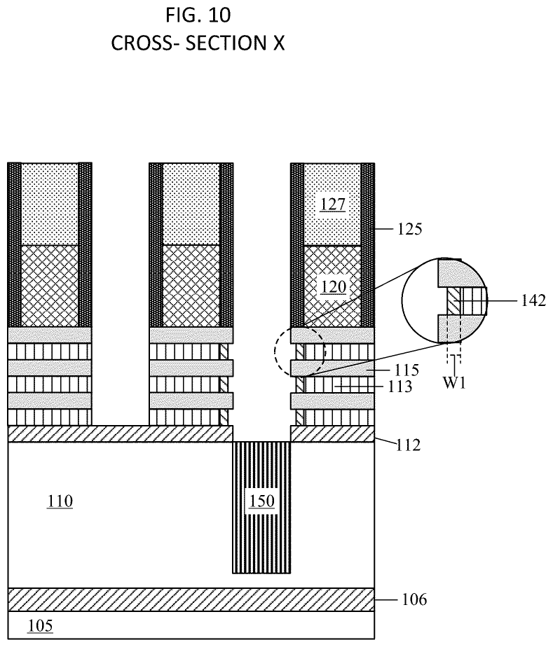

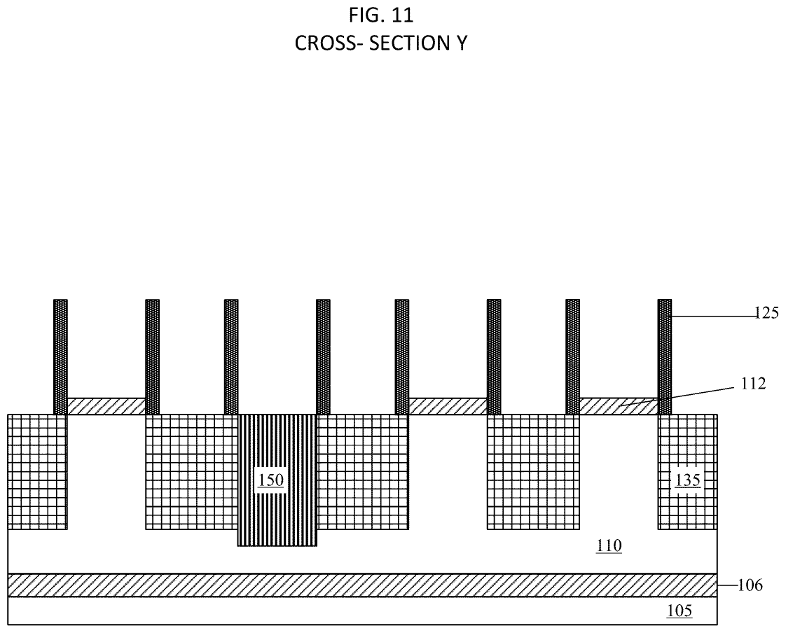

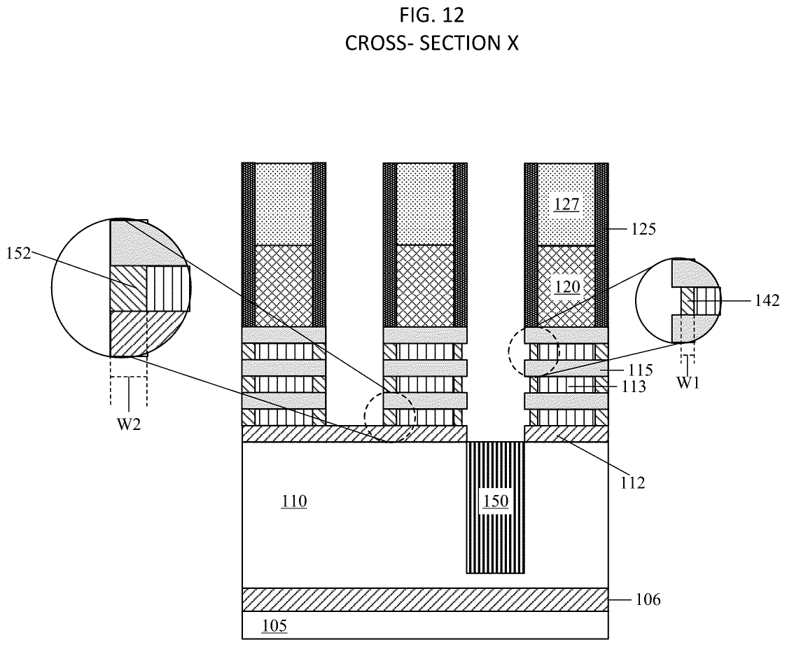

FIGS. 10 and 11 illustrate the processing stage after the removal of the first lithography layer 140 and the formation of the placeholder 150. The first lithography layer 140 is removed and a placeholder 150 is formed within the placeholder trench 141. FIG. 12 illustrates the processing stage after the recessing of the sacrificial layers 113 and the formation of the second inner spacer 152. The sacrificial layers 113 exposed by the removal of the first lithography layer 140 are recessed to create an empty space (not shown). These empty spaces are filled in to form the second inner spacer 152. The second inner spacer 152 will also be referred to as the thicker inner spacer 152. The second inner spacer 152 extends to the end of the adjacent channel layers 115 as seen in the magnified image of the second inner spacer 152. When comparing the two magnified images it is shown that the first inner spacer 142 does not reach the end of the channel layer 115 while the second inner spacer 152 does. The second inner spacer 152 has a second width W2 in the range of about 5 to 8 nanometers. The second width W2, or thickness, dimensions is measured perpendicular to the gate direction. Therefore, the second width W2 of the second inner spacer 152 is larger than the first width W1 of the first inner spacer 142, as measured perpendicular to the gate direction. The second inner spacer 152 (or thicker inner spacer) will be located directly adjacent to the drain epi, to prevent or reduce a parasitic capacitance will form between the drain epi and a gate.

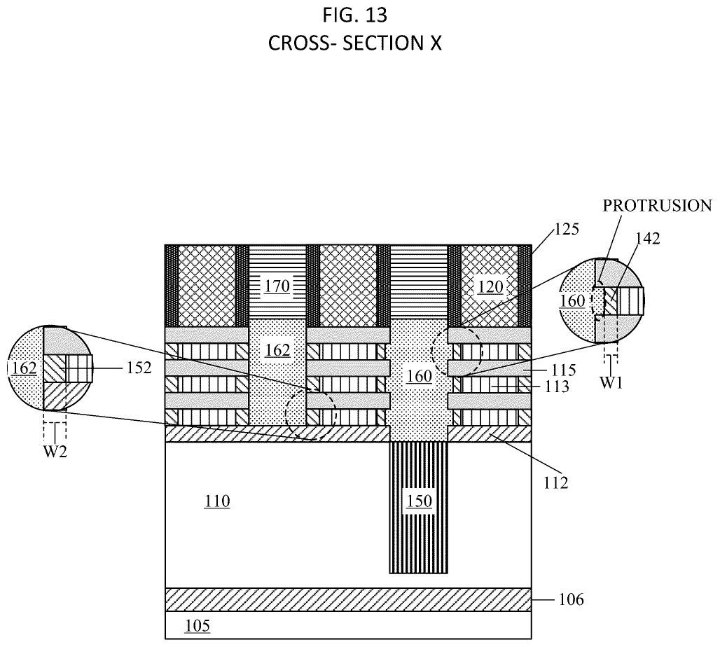

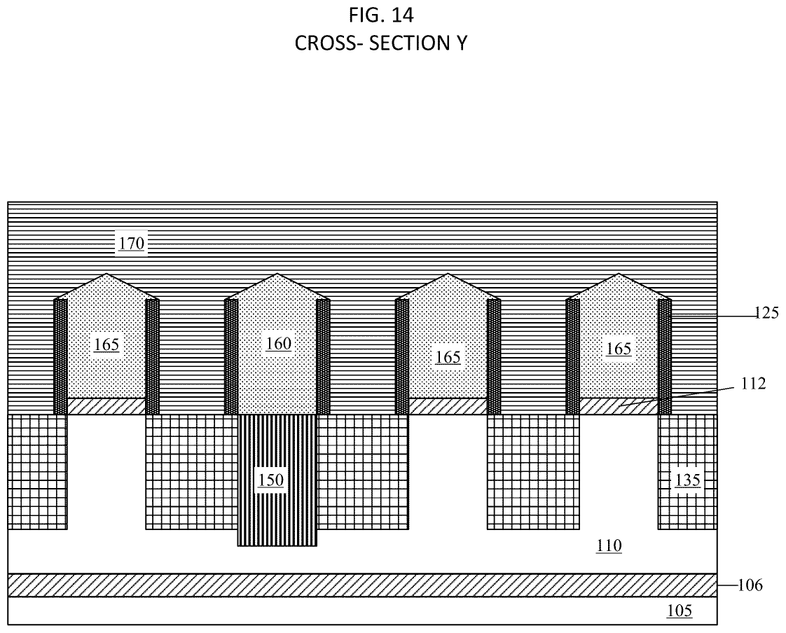

FIGS. 13 and 14 illustrate the processing stage after the formation of the source/drain epis 160, 162, 165, and the formation of the frontside interlayer dielectric layer 170. The source/drain epis are epitaxially grown in the source/drain regions. A source epi 160 is grown on top of the placeholder 150. The source epi 160 is located adjacent to the first inner spacer 142. The source epi 160 has a plurality of small protrusions that extends into the space adjacent to the channel layer layers 115 and adjacent to the first inner spacer 142, as seen in the magnified image of the first inner spacer 142. A drain epi 162 is located adjacent to the second inner spacer 152. The drain epi 162 does not include a protrusion component that is found on the source epi 160. The source/drain epis 165 are formed in adjacent source/drain regions and can be either a drain epi or a source epi. The source/drains epis 160, 162, 165 can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques. A frontside interlayer dielectric layer 170 is formed on top of the source/drains epis 160, 162, 165, on top of the shallow trench isolation layer 136, and around the gate spacer 125. The hardmask 127 is removed to expose the underlying dummy gate 120.

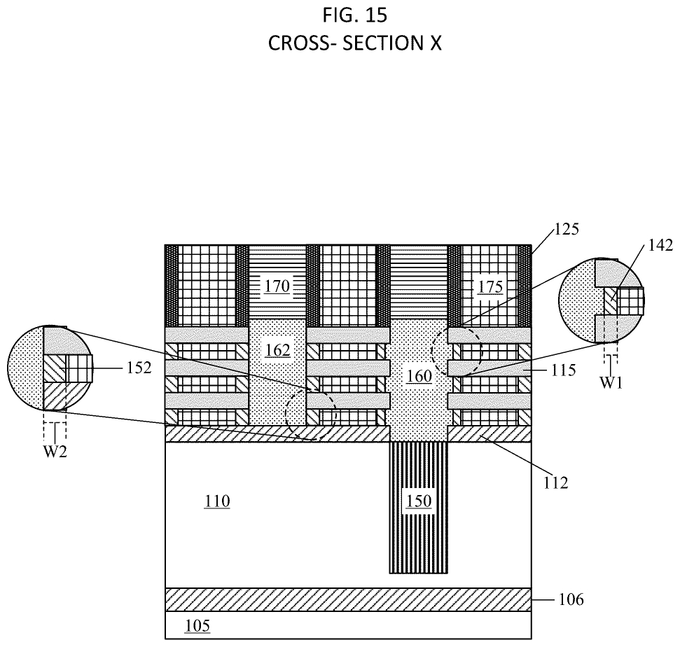

FIG. 15 illustrates the processing stage after the removal of the dummy gate 120, and the sacrificial layers 113 and the formation of the gate 175. Dummy gate 120 and the sacrificial layers 113 are removed to create empty space around the channel layers 115. Gate 175 is formed in this empty space. Gate 175 can be comprised of, for example, a gate dielectric liner, such as high-k dielectric like HfO₂, ZrO₂, HfLₐOₓ, etc., and work function layers, such as TIN, TiAlC, TiC, etc., and conductive metal fills, like W.

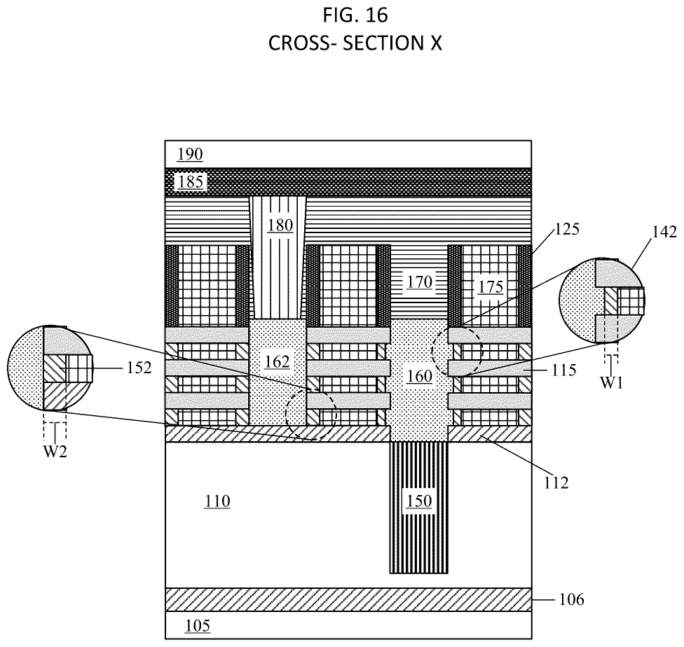

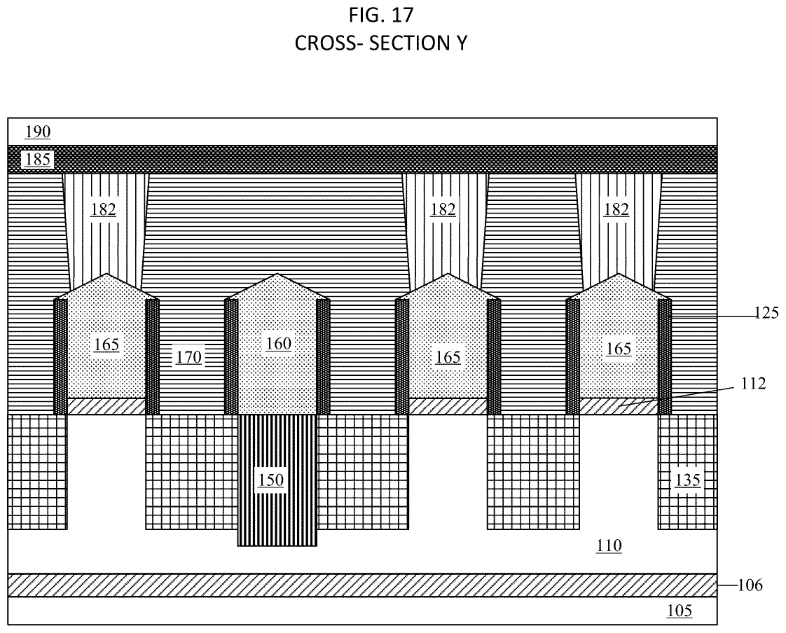

FIGS. 16 and 17 illustrate the processing stage after the formation of the additional frontside interlayer dielectric layer 170, formation of frontside source/drain contacts 180, 182, a back-end-of-the-line (BEOL) layer 185, and a carrier wafer 190. Additional frontside interlayer dielectric layer 170 material is added so that the frontside interlayer dielectric layer 170 extends on top of the gates 175. A plurality of trenches (not shown) are formed in the frontside interlayer dielectric layer 170 and filled with a conductive metal to form the frontside contacts 180, 182. A frontside contact 180 is connected to drain epi 162, as illustrated in FIG. 16. Frontside contacts 182 are connected to the source/drain epi 165, as illustrated in FIG. 17. Additionally, some of the trenches filled in with the conductive metal will form frontside gate contacts (not shown). A back-end-of-the-line (BEOL) layer 185 is formed on top of the frontside interlayer dielectric layer 170 and on top of the frontside contacts 180, 182. A carrier wafer 190 is located on top of the BEOL layer 185.

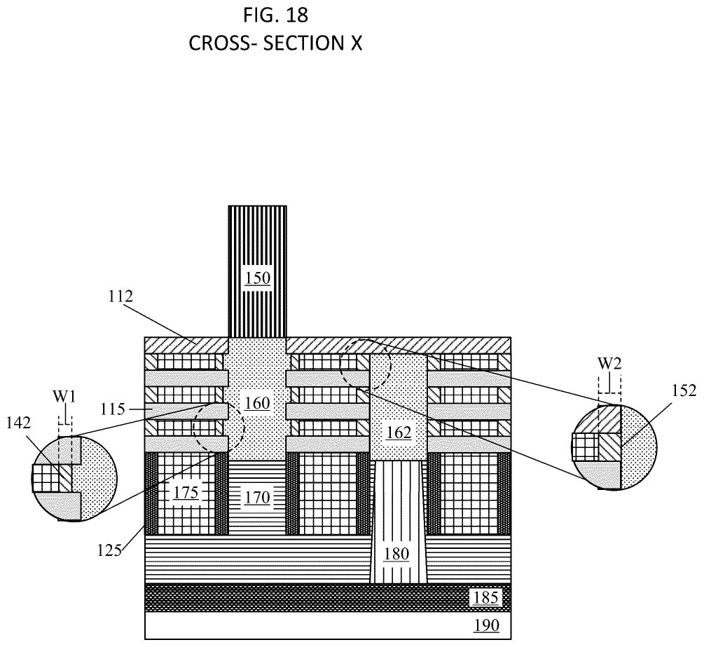

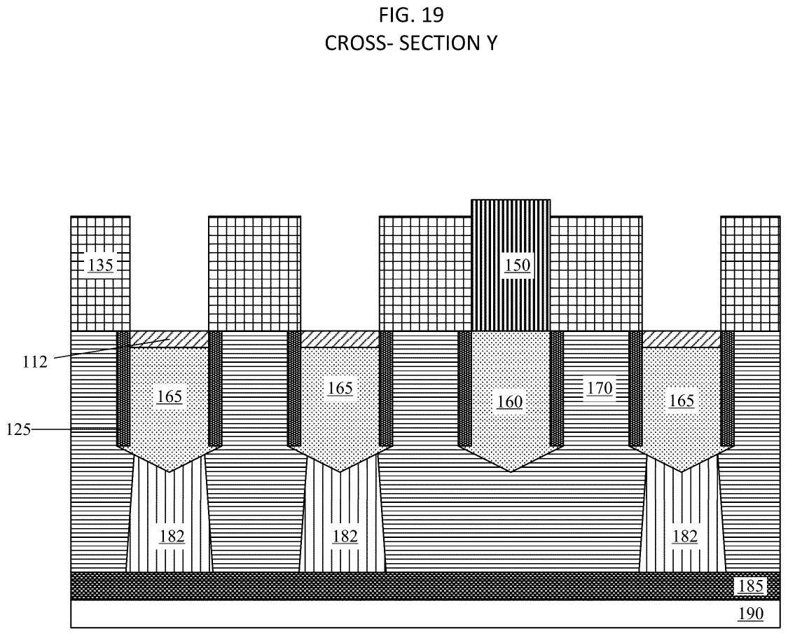

FIGS. 18 and 19 illustrate the processing stage after flipping over the nano stacks for backside processing and the removal of the first substrate 105, the etch stop 106, and the second substrate 110. FIGS. 2-17 illustrate the frontside processing of the nano stacks or nanosheet transistors. The nano stacks or nanosheet transistors are flipped over to allow for backside processing of the devices. FIGS. 18-23 illustrate the backside processing of the nano stacks or nanosheet transistors. The first substrate 105, the etch stop 106, and the second substrate 110 are systematically removed to expose the placeholder 150, the shallow trench isolation layer 135, and a backside surface of the bottom dielectric isolation layer 112.

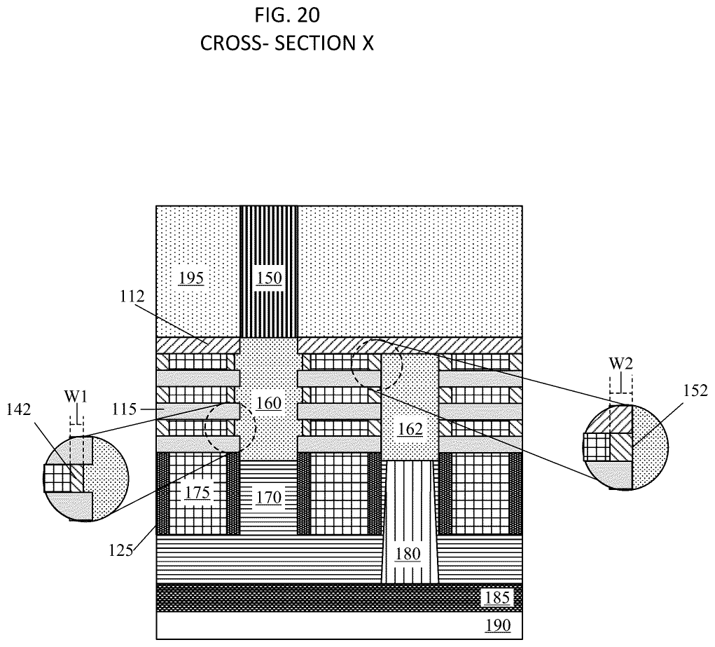

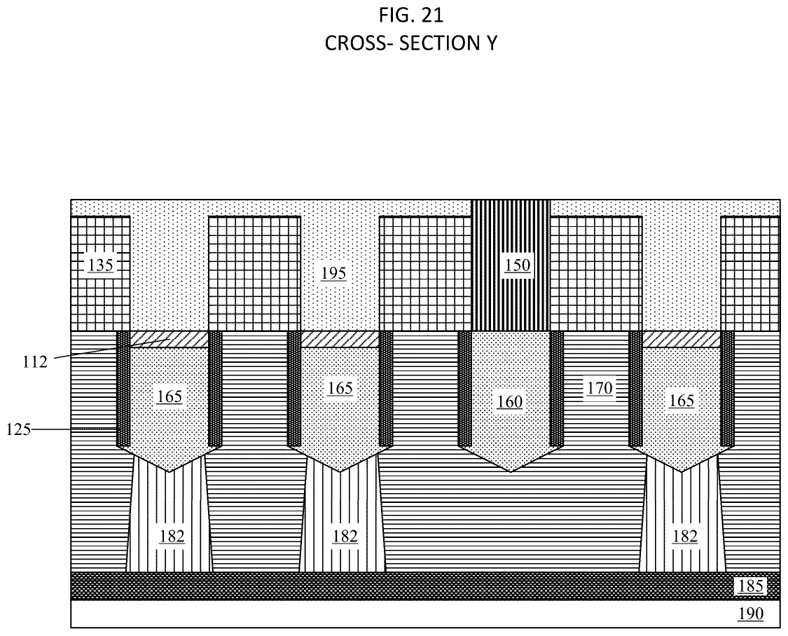

FIGS. 20 and 21 illustrate the processing stage after formation of a backside interlayer dielectric layer 195. A backside interlayer dielectric layer 195 is formed on the backside surface of the bottom dielectric isolation layer 112, around the placeholder 150, and around the shallow trench isolation layer 135.

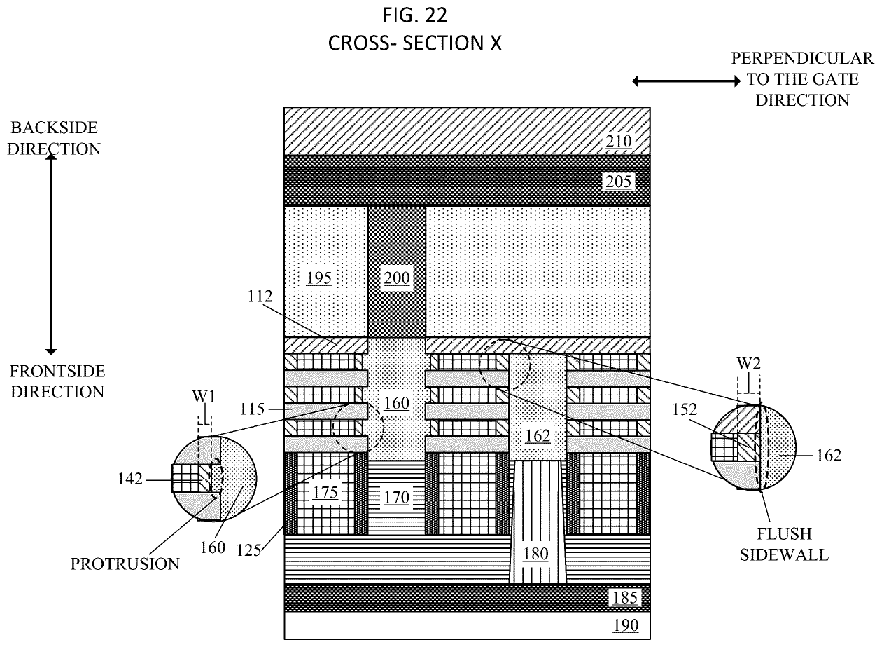

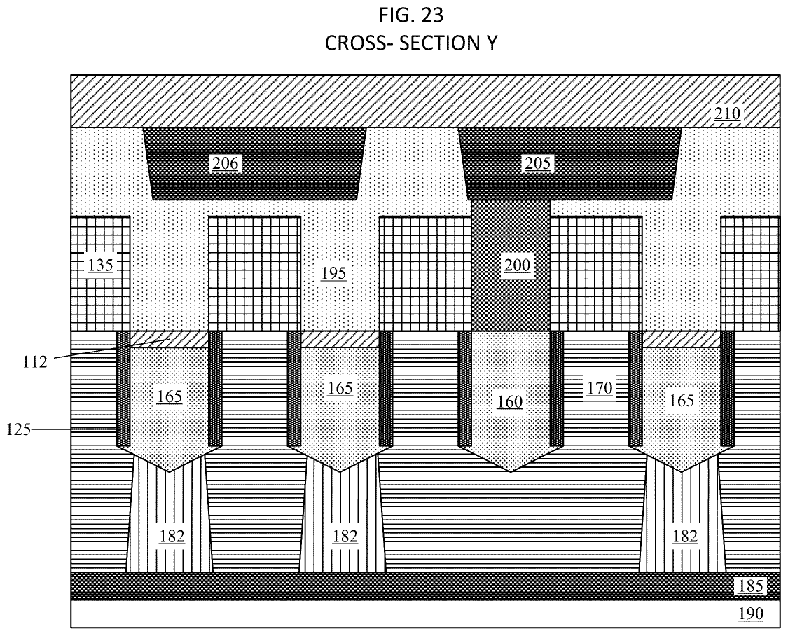

FIGS. 22 and 23 illustrate the processing stage after the removal of the placeholder 150, formation of the backside contact 200, formation of a backside metal lines 205, 206, and the formation of a backside-power-distribution-network (BSPDN) 210. Placeholder 150 is removed to create a trench that exposes the backside surface of source epi 160. The trench is filled in with a conductive metal to form the backside contact 200. The backside contact 200 is in contact with the backside surface of the source epi 160. Additional backside interlayer dielectric layer 195 material is added to increase the height of the layer. A plurality of trenches (not shown) are formed in the backside interlayer dielectric layer 195. These trenches are filled in with a conductive metal to form a plurality of metal lines 205, 206. Each of the plurality of metal lines 205, 206 can be different type of metal line, for example, VSS, VDD, signal line, or a different type of metal line. A backside-power-distribution-network (BSPDN) is formed on top of the plurality of metal lines 205, 206, and on top of the backside interlayer dielectric layer 195.

A microelectronic structure that includes a nanosheet transistor. The nanosheet transistor includes a source epi 160 and a drain epi 162. A first inner spacer 142 located adjacent to the source epi 160, where the first inner spacer has a first width W1 as measured perpendicular to a gate direction. A second inner spacer 152 located adjacent to the drain epi 162. The second inner spacer 152 has second width W2 as measured perpendicular to the gate direction. The first width W1 and the second width W2 are different.

The first width W1 is smaller than the second width W2. The first width W1 is in the range of about 1 nm to 4 nm. The second width W2 is in the range of about 5 nm to 8 nm.

A microelectronic structure that includes a nanosheet transistor. The nanosheet transistor includes a source epi 160 and a drain epi 162. The nanosheet transistor includes a plurality of channel layers 115. A first inner spacer 142 located adjacent to the source epi 160, where the first inner spacer has a first width W1 as measured perpendicular to a gate direction. A second inner spacer 152 located adjacent to the drain epi 162. The second inner spacer 152 has second width W2 as measured perpendicular to the gate direction. The first width W1 and the second width W2 are different.

A sidewall of the drain epi 162 is in direct contact with the channel layers 115 and the second inner spacer 152. The sidewall of the drain epi 162 is a straight vertical surface. A sidewall of the source epi 160 includes a plurality of source epi 160 protrusions. At least the top surface of the source epi 160 protrusion is in contact with a bottom surface of a channel layer 115. A sidewall of the source epi 160 protrusion is in contact with the first inner spacer 142.

The first width W1 is smaller than the second width W2. The first width W1 is in the range of about 1 nm to 4 nm. The second width W2 is in the range of about 5 nm to 8 nm.

A frontside contact in contact 180 with a frontside surface of the drain epi 162. A backside contact 200 in contact a backside surface of the source epi 160.

The first inner spacer 142 and the second inner spacer 152 are comprised of different materials. Furthermore, the first inner spacer 142 (e.g., the thinner inner spacer) has dielectric constant higher k value than the second inner spacer 152 (e.g., the thicker inner spacer). The first inner spacer 142 and the second inner spacer 152 are comprised of the same material.

A method including the steps of forming a nanosheet transistor. The nanosheet transistor includes a source epi 160 and a drain epi 162. Forming a first inner spacer 142 located adjacent to the source epi 160, where the first inner spacer 142 has a first width W1 as measured perpendicular to a gate direction. Forming a second inner spacer 152 located adjacent to the drain epi 162. The second inner spacer 152 has second width W2 as measured perpendicular to the gate direction. The first width W1 and the second width W2 are different.

The first inner spacer 142 and the second inner spacer 152 are not formed simultaneously. The first width W1 is smaller than the second width W2. The first width W1 is in the range of about 1 nm to 4 nm, and the second width W2 is in the range of about 5 nm to 8 nm.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic structure comprising:
a nanosheet transistor, wherein the nanosheet transistor includes a source epi and a drain epi;
a first inner spacer located adjacent to the source epi, wherein the first inner spacer has a first width as measured perpendicular to a gate direction; and
a second inner spacer located adjacent to the drain epi, wherein the second inner spacer has second width as measured perpendicular to the gate direction, wherein the first width and the second width are different.

2. The microelectronic structure of claim 1, wherein the first width is smaller than the second width.

3. The microelectronic structure of claim 2, wherein the first width is in the range of about 1 nm to 4 nm.

4. The microelectronic structure of claim 2, wherein the second width is in the range of about 5 nm to 8 nm.

5. A microelectronic structure comprising:
a nanosheet transistor, wherein the nanosheet transistor includes a source epi and a drain epi, wherein the nanosheet transistor includes a plurality of channel layers;
a first inner spacer located adjacent to the source epi, wherein the first inner spacer has a first width as measured perpendicular to a gate direction; and
a second inner spacer located adjacent to the drain epi, wherein the second inner spacer has second width as measured perpendicular to the gate direction, wherein the first width and the second width are different.

6. The microelectronic structure of claim 5, wherein a sidewall of the drain epi is in direct contact with the channel layers and the second inner spacer, wherein the sidewall of the drain epi is a straight vertical surface.

7. The microelectronic structure of claim 5, wherein a sidewall of the source epi includes a plurality of source epi protrusions.

8. The microelectronic structure of claim 7, wherein at least a top surface of the source epi protrusion is in contact with a bottom surface of a channel layer.

9. The microelectronic structure of claim 8, wherein a sidewall of the source epi protrusion is in contact with the first inner spacer.

10. The microelectronic structure of claim 5, wherein the first width is smaller than the second width.

11. The microelectronic structure of claim 10, wherein the first width is in the range of about 1 nm to 4 nm.

12. The microelectronic structure of claim 11, wherein the second width is in the range of about 5 nm to 8 nm.

13. The microelectronic structure of claim 5, further comprising:
a frontside contact in contact with a frontside surface of the drain epi.

14. The microelectronic structure of claim 13, further comprising:
a backside contact in contact a backside surface of the source epi.

15. The microelectronic structure of claim 5, wherein the first inner spacer and the second inner spacer are comprised of different materials, wherein the first inner spacer includes a first material that has a first dielectric constant K value, wherein the second inner spacer includes a second material that has a second dielectric constant K value, and wherein the first dielectric constant K value is higher than the second dielectric constant K value.

16. The microelectronic structure of claim 5, wherein the first inner spacer and the second inner spacer are comprised of the same material.

17. A method comprising:
forming a nanosheet transistor, wherein the nanosheet transistor includes a source epi and a drain epi;
forming a first inner spacer adjacent to the source epi, wherein the first inner spacer has a first width as measured perpendicular to a gate direction; and
forming a second inner spacer adjacent to the drain epi, wherein the second inner spacer has second width as measured perpendicular to the gate direction, wherein the first width and the second width are different.

18. The method of claim 17, wherein the first inner spacer and the second inner spacer are not formed simultaneously.

19. The method of claim 18, wherein the first width is smaller than the second width.

20. The method of claim 19, wherein the first width is in the range of about 1 nm to 4 nm, and wherein the second width is in the range of about 5 nm to 8 nm.
